(19) United States
(12) Patent Application Publication
(10) Pub. No.: US 2025/0372463 A1
(43) Pub. Date: Dec. 4, 2025

(54) TESTING STRUCTURE FOR SEMICONDUCTOR DEVICES

(71) Applicant: International Business Machines Corporation, Armonk, NY (US)

(72) Inventors: Mark Christopher Johnson, South Burlington, VT (US); John Knickerbocker, Monroe, NY (US); Ishtiaq Ahsan, Halfmoon, NY (US); Pablo Nieves, Pinebluff, NC (US)

(21) Appl. No.: 18/731,542

(22) Filed: Jun. 3, 2024

(51) Int. Cl. H01L 21/66; G01R 1/073; G01R 31/28

(52) U.S. Cl. CPC H01L 22/32; G01R 1/07342; G01R 31/2886

(57) ABSTRACT

A semiconductor test structure includes a first surface comprising a plurality of first conductive contacts spaced apart from each other at a first pitch, and a second surface located opposite the first surface and comprising a plurality of second conductive contacts spaced apart from each other at a second pitch. The second pitch is less than the first pitch, and respective ones of the plurality of first conductive contacts are electrically connected to one or more respective ones of the plurality of second conductive contacts.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide semiconductor testing structures.

In one embodiment, a semiconductor test structure includes a first surface including a plurality of first conductive contacts spaced apart from each other at a first pitch, and a second surface located opposite the first surface and including a plurality of second conductive contacts spaced apart from each other at a second pitch. The second pitch is less than the first pitch, and respective ones of the plurality of first conductive contacts are electrically connected to one or more respective ones of the plurality of second conductive contacts.

In another embodiment, a semiconductor test structure includes a plurality of first conductive contacts disposed on a first side of the semiconductor test structure, wherein the plurality of first conductive contacts are spaced apart from each other at a first pitch, and a plurality of second conductive contacts spaced apart from each other at a second pitch and disposed on a second side of the semiconductor test structure. The second side is located opposite the first side, and the second pitch is less than the first pitch. Respective ones of the plurality of first conductive contacts are electrically connected to one or more respective ones of the plurality of second conductive contacts.

In another embodiment, a semiconductor test structure includes a first substrate bonded to a second substrate, a plurality of first conductive contacts disposed on a first side of the first substrate, wherein the plurality of first conductive contacts are spaced apart from each other at a first pitch, and a plurality of second conductive contacts spaced apart from each other at a second pitch and disposed on a second side of the first substrate. The second side is located opposite the first side, and the second pitch is less than the first pitch. Respective ones of the plurality of first conductive contacts are electrically connected to one or more respective ones of the plurality of second conductive contacts. The second substrate includes a plurality of third contacts of a device under test and the respective ones of the plurality of second conductive contacts electrically contact respective ones of the plurality of third contacts.

These and other features and advantages of embodiments described herein will become more apparent from the accompanying drawings and the following detailed description.

### BRIEF DESCRIPTION OF THE DRAWINGS

FIG. 1 depicts a block diagram of different levels of a semiconductor test structure, according to an embodiment of the invention.

FIG. 2 depicts a high-level cross-sectional view of a test substrate that is to be bonded to a device under test (DUT) structure, according to an embodiment of the invention.

FIGS. 3A and 3B depict high-level cross-sectional views illustrating preparation of a DUT structure, according to an embodiment of the invention.

FIG. 3C depicts a high-level cross-sectional view of a test substrate that is to be bonded to a DUT structure, according to an embodiment of the invention.

FIG. 4 depicts a high-level cross-sectional view of a portion of a test substrate bonded to a portion of a DUT structure, according to an embodiment of the invention.

FIGS. 5A, 5B and 5C depict high-level cross-sectional views of respective test substrates with different types of contacts that are to be bonded to respective DUT structures, according to an embodiment of the invention.

FIGS. 6A, 6B and 6C depict high-level cross-sectional views of the respective test substrates with different types of contacts bonded to the respective DUT structures, according to an embodiment of the invention.

FIGS. 7A, 7B and 7C depict high-level cross-sectional views of the respective test substrates with different types of contacts following de-bonding from the respective DUT structures, according to an embodiment of the invention.

FIGS. 8A, 8B and 8C depict high-level cross-sectional views of the respective test substrates with different types of contacts following preparation for subsequent bonding to respective additional DUT structures, according to an embodiment of the invention.

### DETAILED DESCRIPTION

Illustrative embodiments of the invention may be described herein in the context of illustrative methods for forming semiconductor testing structures, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

The term “semiconductor integrated circuit chip” as used herein refers to a semiconductor die which includes an integrated circuit, which is fabricated on a semiconductor wafer including multiple dies, and which can be diced (cut) from a semiconductor wafer using a die singulation process to provide a singulated die for packaging. In the context of semiconductor integrated circuits, a die is a block of semiconductor material on which a given functional circuit is fabricated (e.g., memory circuit, processor circuitry, etc.). The terms “chip” and “die” are used interchangeably herein.

In a non-limiting example of a device which may be tested, a field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to structural gains (e.g., such as 30-40% structural gains for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation stacked FET devices.

Interconnect pitch refers to the distance from the center or edge of a conductive contact (e.g., bump, ubump, pad or other interconnect surface) to the center or edge of another conductive contact. As noted hereinabove, semiconductors and integrated circuit chips continue to decrease in size. Present technology, which is at or approaching atomic level scaling of certain micro-devices has resulted in smaller interconnect pitches. However, test probe technology is not advancing as quickly as interconnect technology. As a result, there is a lack of test probes with small enough pitches that can be used to contact, apply signals to and/or measure signals on interconnect surfaces.

In an effort to address the noted issues with current test probes, the illustrative embodiments provide a semiconductor test structure in which a first surface (e.g., top surface) of a test layer includes a plurality of first conductive contacts (e.g., “test pads”) arranged at pitches corresponding to those of existing test probes so that the test probes can be used to contact the first conductive contacts, apply signals (e.g., voltages) to the first conductive contacts and/or measure signals (e.g., voltages) through the first conductive contacts. Advantageously, a second surface of the test layer (e.g., bottom surface) opposite the first surface includes a plurality of second conductive contacts spaced apart from each other at the smaller pitches corresponding to those the current interconnects. In illustrative embodiments, the first conductive contacts are directly wired to the second conductive contacts on the second surface or are electrically connected to the second conductive contacts through one or more design for test (DFT) circuits including, for example, microcontrollers, phase-locked loop (PLL) circuits, built-in self-test (BIST) engines, sensors, or other types of circuits that can be used in connection with determining if a DUT is a known good die (KGD). The DFT circuits may be wired to a redistribution layer (RDL) that is designed to distribute and match signals to intended interconnects on the DUT.

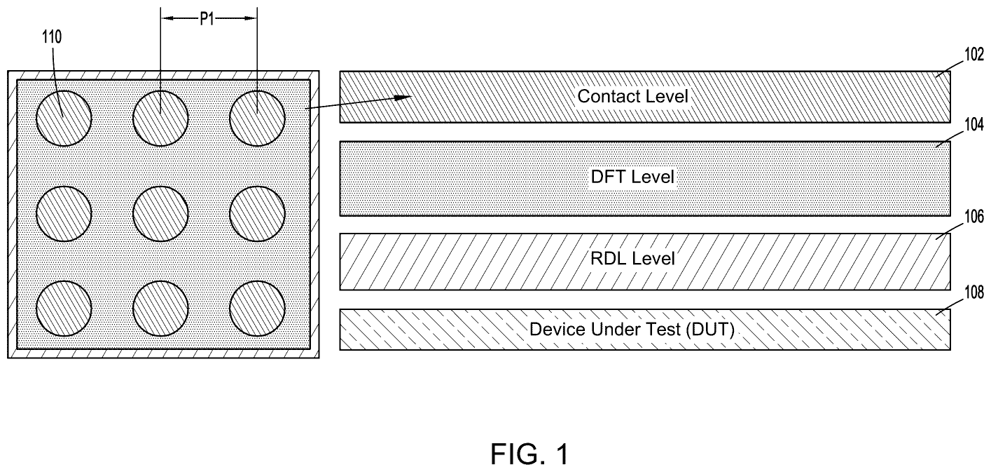

In more detail, referring to FIG. 1, a contact level 102 of a test structure includes the plurality of first conductive contacts 110 spaced apart from each other at pitch P1 corresponding to a pitch of standard test probes. Alternatively, the pitch P1 of the plurality of first conductive contacts 110 of the contact level 102 can be customized. The DFT level 104 includes DFT circuits designed to meet testing requirements for a DUT 108. DFT circuits of the DFT level 104 connect with interconnects in the contact level 102 and RDL level 106. A pitch and layout of interconnects of a DUT is defined. If a DFT level 104 including DFT circuits is used, and the RDL level 106 is designed to match the interconnects of the DUT to the DFT level 104.

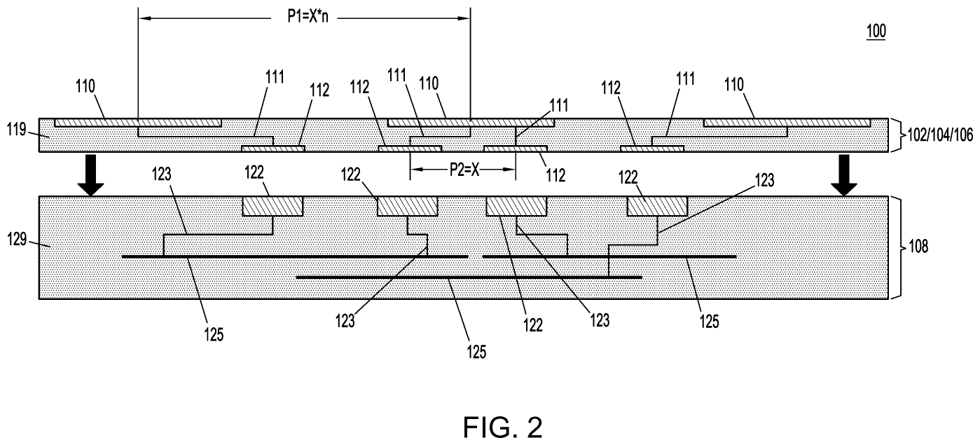

Referring, for example, to the semiconductor structure 100 in FIG. 2, a first substrate 119 and a second substrate 129 may be, for example, a semiconductor chip, die and/or wafer. As explained in more detail herein, the first substrate 119 can be temporarily or permanently bonded to the second substrate 129. The first substrate 119, in illustrative embodiments, includes the contact level 102, DFT level 104 and RDL level 106, and the second substrate 129 includes the DUT 108. The contact level 102, DFT level 104 and RDL level 106 may collectively be referred to as a “test layer” herein. The first and second substrates 119 and 129 may include semiconductor material including, but not limited to, silicon (Si), III-V, II-V compound semiconductor materials or other like semiconductor materials. In addition, multiple layers of the semiconductor materials can be used as the semiconductor material of the first and second substrates 119 and 129.

As can be seen, a plurality of first conductive contacts 110 are disposed on a first side (e.g., top side) of the first substrate 119, and are spaced apart from each other at a first pitch P1, which is defined as X*n, where n is a number greater than 1. A plurality of second conductive contacts 112 are spaced apart from each other at a second pitch P2 and are disposed on a second side (e.g., bottom side) of the first substrate 119. As can be seen, the second side is located opposite the first side. The second pitch P2 is less than the first pitch, and is defined as X. The lines 111 represent electrical connections between the plurality of first conductive contacts 110 and the plurality of second conductive contacts 112. In some embodiments, wires provide direct electrical connections between respective ones of the plurality of first conductive contacts 110 and one or more respective ones of the plurality of second conductive contacts 112. Alternatively, the respective ones of the plurality of first conductive contacts 110 are electrically connected to one or more of the respective ones of the plurality of second conductive contacts 112 via one or more circuits. The one more circuits may include one or more DFT circuits formed in a DFT level 104 on the first substrate 119. The DFT circuits may include, for example, one or more PLL circuits, one or more microcontrollers, one or more BIST engines and/or one or more sensors.

The second substrate 129 includes a plurality of third conductive contacts 122 of a DUT 108 and once the first substrate 119 is bonded to the second substrate 129, the respective ones of the plurality of second conductive contacts 112 electrically contact respective ones of the plurality of third conductive contacts 122. In some embodiments, the DFT circuits are wired to an RDL level 106 on the first substrate 119, wherein the RDL level 106 is configured to distribute signals applied to the DFT circuits to one or more interconnects (e.g., the plurality of third conductive contacts 122) of a DUT 108.

The plurality of third conductive contacts 122 can be connected to circuitry and or semiconductor devices (represented by lines 125) through one or more connecting lines or circuits (represented by lines 123). The second pitch P2 is the same as a pitch at which the respective ones of the plurality of third conductive contacts 122 are spaced apart from each other. As noted hereinabove, pitches (e.g., pitches P1 and P2) can refer to the distance from the center or edge of a conductive contact to the center or edge of another conductive contact. As noted hereinabove, the first pitch is the same as a pitch at which respective ones of a plurality of test probes are spaced apart from each other.

In illustrative embodiments, the plurality of first conductive contacts 110 and the plurality of third conductive contacts 122 include, but are not limited to, conductive pads, conductive bumps (e.g., ubumps) or other conductive contacts (e.g., interconnects). The plurality of second conductive contacts 112 may include, but are not limited to, probe tips, scrub tips, pins, vias, pillars, wires or other conductive contacts (e.g., interconnects). In illustrative embodiments, the first conductive contacts 110, second conductive contacts 112 and the third conductive contacts 122 may be copper (Cu) with nickel (Ni), tungsten (W), molybdenum (Mo) or alternate hardened surfaces or may be W, Mo, ruthenium (Ru), platinum (Pt) with alternate surface materials.

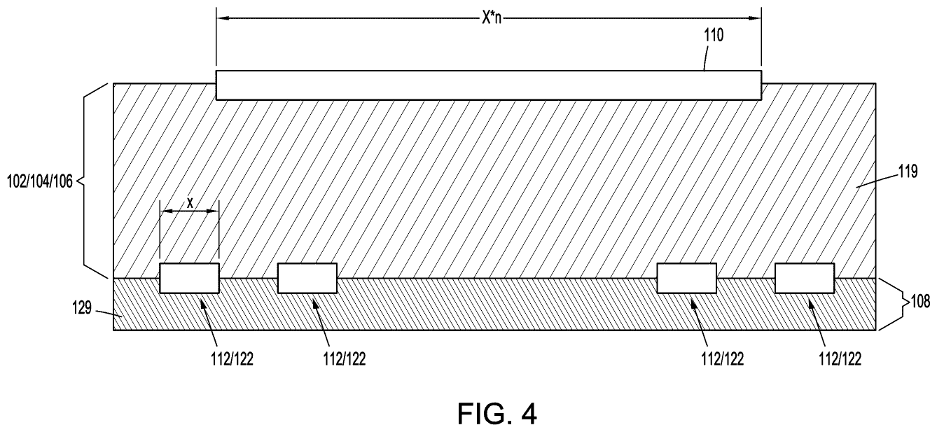

As explained in more detail herein, the first substrate 119 is configured to be bonded to and de-bonded from the second substrate 129 including the DUT 108. For example, FIG. 4 depicts a high-level cross-sectional view of a portion of the first substrate 119 bonded to a portion of a second substrate 129 including a DUT 108. FIG. 4 depicts a first conductive contact 110 having an end-to-end pitch of X*n and bonded second and third conductive contacts 112/122 having an end-to-end pitch of X. In an illustrative embodiment, the first substrate 119 is a test layer including contact level 102, DFT level 104 and RDL level 106. In one or more embodiments, the first substrate 119 may also be bonded to a silicon probe card that can be used for multiple products and provide off-chip DFT circuits to assist with testing of DUTs.

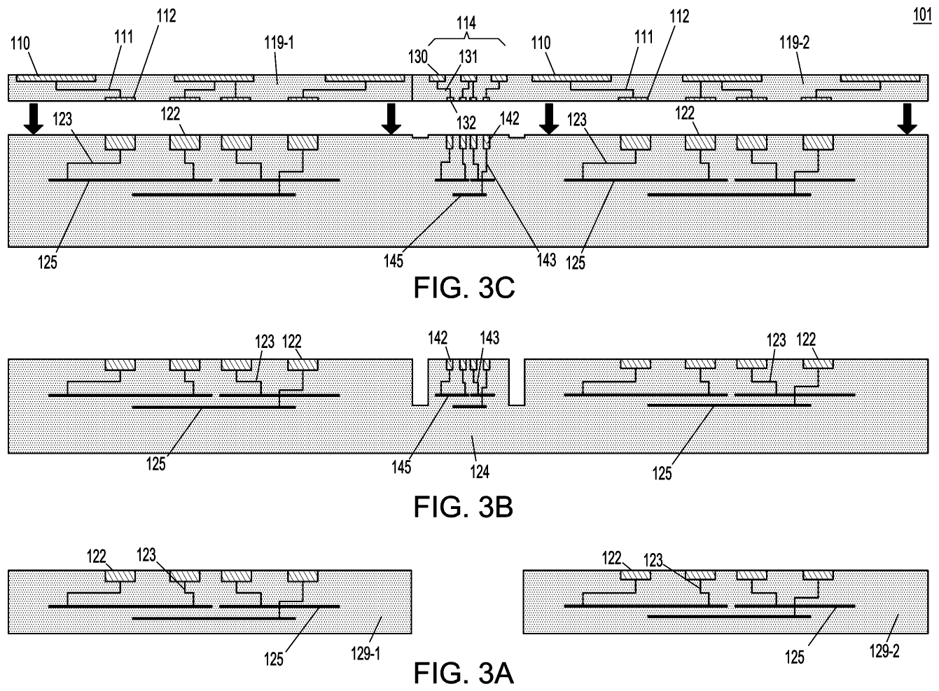

FIGS. 3A and 3B depict high-level cross-sectional views illustrating preparation of a DUT structure, and FIG. 3C depicts a high-level cross-sectional view of a test substrate that is to be bonded to a DUT structure. As can be seen in FIG. 3C, a semiconductor structure 101 includes a test substrate with first and second test substrate portions 119-1 and 119-2, and a first chiplet 114. The first and second test substrate portions 119-1 and 119-2 are each the same as the first substrate 119 described in connection with FIG. 2. As can be seen in FIGS. 3A and 3B, the semiconductor structure 101 further includes a DUT structure with first and second DUT substrate portions 129-1 and 129-2, and a second chiplet 124. The first and second DUT substrate portions 129-1 and 129-2 are each the same as the second substrate 129 described in connection with FIG. 2. In FIGS. 3B and 3C, die-to-wafer bonding is used to create the test substrate including the first and second test substrate portions 119-1 and 119-2, and the first chiplet 114, and to create the DUT structure including the first and second DUT substrate portions 129-1 and 129-2, and a second chiplet 124.

As shown in FIG. 3C, the first and second test substrate portions 119-1 and 119-2 are joined to each other with the first chiplet 114 joined between each of the first and second test substrate portions 119-1 and 119-2. As shown in FIGS. 3B and 3C, the first and second DUT substrate portions 129-1 and 129-2 are joined to each other with the second chiplet 124 joined between each of the first and second DUT substrate portions 129-1 and 129-2. In illustrative embodiments, the second chiplet 124 may be a test-site and/or comprise DFT circuitry.

Similar to the first conductive contacts 110, a plurality of first chiplet conductive contacts 130 are disposed on a first side (e.g., top side) of the first chiplet 114, and are spaced apart from each other at one pitch. A plurality of second chiplet conductive contacts 132 are spaced apart from each other at another pitch and are disposed on a second side (e.g., bottom side) of the first chiplet 114. As can be seen, the second side is located opposite the first side. The pitch of the first chiplet conductive contacts 130 can correspond to a pitch of test probes. The pitch of the second chiplet conductive contacts 132 is less than the pitch of the first chiplet conductive contacts 130. The lines 131 represent electrical connections between the plurality of first chiplet conductive contacts 130 and the plurality of second chiplet conductive contacts 132. In some embodiments, wires provide direct electrical connections between respective ones of the plurality of first chiplet conductive contacts 130 and one or more respective ones of the plurality of second chiplet conductive contacts 132. Alternatively, the respective ones of the plurality of first chiplet conductive contacts 130 are electrically connected to one or more of the respective ones of the plurality of second chiplet conductive contacts 132 via one or more circuits. The one more circuits may include one or more DFT circuits formed in a DFT level 104 on the test substrate. The DFT circuits may include, for example, one or more PLL circuits, one or more microcontrollers, one or more BIST engines and/or one or more sensors.

The second chiplet 124 includes a plurality of third chiplet contacts 142 of a DUT structure and once the test substrate, including the first chiplet 114 and the first and second test substrate portions 119-1 and 119-2, is bonded to the DUT structure including the second chiplet 124 and the first and second DUT substrate portions 129-1 and 129-2, the respective ones of the plurality of second chiplet conductive contacts 132 electrically contact respective ones of the plurality of third chiplet contacts 142. In some embodiments, the DFT circuits are wired to an RDL level 106 on the test substrate, wherein the RDL level 106 is configured to distribute signals applied to the DFT circuits to one or more interconnects (e.g., the plurality of third chiplet contacts 142) of the DUT structure.

The plurality of third chiplet contacts 142 can be connected to circuitry and or semiconductor devices (represented by lines 145) through one or more connecting lines or circuits (represented by lines 143). The pitch of the second chiplet conductive contacts 132 is the same as a pitch at which the respective ones of the plurality of third chiplet contacts 142 are spaced apart from each other.

In illustrative embodiments, the plurality of first chiplet conductive contacts 130 and the plurality of third chiplet contacts 142 include, but are not limited to, conductive pads, conductive bumps (e.g., ubumps) or other conductive contacts (e.g., interconnects). The plurality of second chiplet conductive contacts 132 may include, but are not limited to, probe tips, scrub tips, pins, vias, pillars, wires or other conductive contacts (e.g., interconnects).

The test substrate, including the first chiplet 114 and the first and second test substrate portions 119-1 and 119-2, is configured to be bonded to and de-bonded from the DUT structure including the second chiplet 124 and the first and second DUT substrate portions 129-1 and 129-2. In addition, the test substrate may be bonded to a silicon probe card that can be used for multiple products and provide off-chip DFT circuits to assist with testing of DUTs.

The first conductive contacts 110 and/or the first chiplet conductive contacts 130 of the contact level 102 each create uniform pitch probe layers that can be contacted by one or more sets of existing test probes. The uniformity of the probe layers and the bonding versatility of the first substrate 119 or other test substrate (e.g., the first chiplet 114 and the first and second test substrate portions 119-1 and 119-2) to the second substrate 129 or other DUT structure (e.g., the second chiplet 124 and the first and second DUT substrate portions 129-1 and 129-2) enables the use of the same probes for multiple products (e.g., multiple DUTs) and the probes are easier and cheaper to produce than having to produce probes corresponding to the interconnect pitches of the DUTs.

DFT circuits are disposed on a substrate as part of a test layer that can be bonded to and de-bonded from substrates corresponding to DUTs, saving valuable silicon area on a packaged module. For example, a test layer is bonded to a DUT and once testing is complete the test layer is de-bonded from the DUT. Alternatively, the test layer can be permanently bonded to a chiplet of the DUT and become part of a package, functioning as a DFT for the entire package.

For dicing street testing, similar to die testing, dicing streets can be used for process tests, BISTs and BIST functional tests during wafer building. Due to the fine pitches of interconnects of the dicing streets, the dicing streets may also benefit from the test layers of the illustrative embodiments, which can be bonded and de-bonded from the dicing street structures. The remaining thinned functional wafers could then be singulated with mechanical, laser and/or plasma or reactive ion etching (RIE) for binning, KGD or scrapped, pending processing of DUT data and/or results.

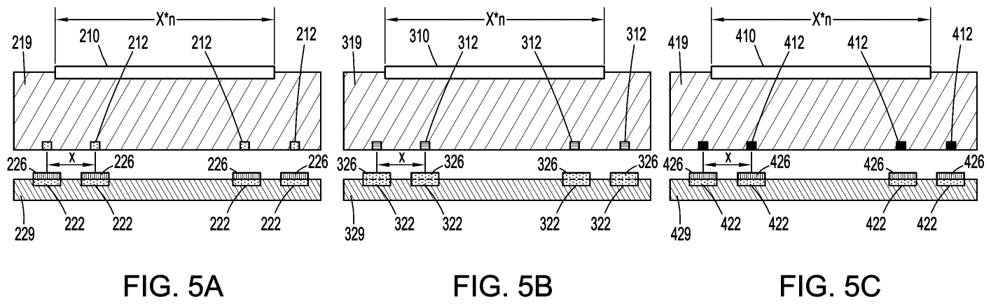

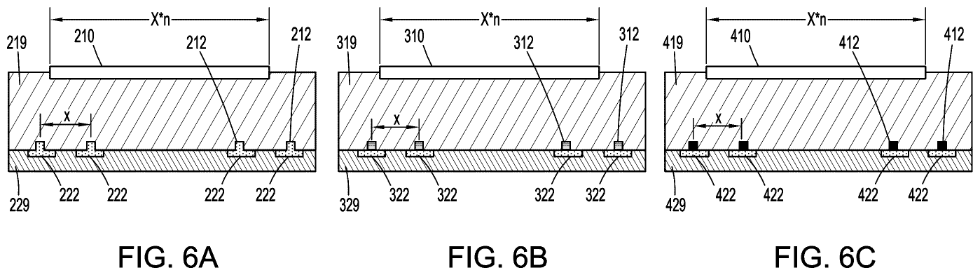

FIGS. 5A, 5B and 5C depict high-level cross-sectional views of respective test substrates 219, 319 and 419 with different types of contacts that are to be bonded to respective DUT substrates 229, 329 and 429. The test substrate 219 includes pins 212 as the conductive contacts, the test substrate 319 includes pads 312 as the conductive contacts and the test substrate 419 includes alternative conductive contacts 412 such as, for example, scrub tips, probe tips, vias, pillar or wires. The pins 212, pads 312 and alternative conductive contacts 412 are the same as or similar to the second conductive contacts 112 described herein. The conductive contacts 210, 310 or 410 are the same as or similar to the first conductive contacts 110 described herein, and serve as contacts for test probes. While FIGS. 5A-5C (and FIGS. 6A-8C) each illustrate one conductive contact 210, 310 and 410, it is to be understood that the test substrates 219, 319 and 419 each include a plurality of conductive contacts 210, 310 and 410 spaced apart from each other at a given pitch (e.g., X*n or other pitch which greater than the pitch of pins 212, pads 312 and alternative conductive contacts 412). The pins 212, pads 312 and alternative conductive contacts 412 can be applied to a full wafer assembly (wafer-to-wafer (W2 W)), to a die or multi-die-to-wafer assembly (D2 W or multi-D2 W), or to a die-to-die or multi-die-to-multi-die assembly (D2D or Multi-D to Multi-D). Like the first conductive contacts 110 and the second conductive contacts 112, the pins 212, pads 312 and alternative conductive contacts 412 are spaced apart from each other at a pitch (X), which is less than the pitch (X*n) of the conductive contacts 210, 310 or 410.

The DUT substrates 229, 329 and 429 respectively include conductive contacts 222, 322 and 422, which are the same as or similar to the third conductive contacts 122 described herein. As can be understood, the conductive contacts 222, 322 and 422 are spaced apart from each other at the same pitch (X) as the pins 212, pads 312 and alternative conductive contacts 412.

The test substrates 219, 319 and 419 (e.g., test layer wafers) are fabricated separately from the DUT substrates 229, 329 and 429. Each of the test substrates 219, 319 and 419 and DUT substrates 229, 329 and 429 can include an on-carrier structure or wafer with materials for wafer or die stacking and bonding of respective test substrates 219, 319 and 419 to respective DUT substrates 229, 329 and 429. As shown in FIGS. 5A-5B, intermediate layers 226, 326 and 426 are respectively deposited on the surfaces of the conductive contacts 222, 322 and 422. The intermediate layers 226, 326 and 426 are respectively disposed between pins 212 and conductive contacts 222, between pads 312 and conductive contacts 322 and between alternative conductive contacts 412 and conductive contacts 422. The intermediate layers 226, 326 and 426 may include conductive layers such as, for example, copper, or solder of varying metal mixtures that may include tin, nickel, silver, gold, zinc, lead or other metals. In some cases, the intermediate layers include release layers that facilitate release (e.g., de-bonding) of the test substrates 219, 319 and 429 from the DUT substrates 229, 329 and 429 and vice versa. The release layers may include, for example, polydimethyl glutarimide that can be dissolved by chemicals to break the bond, or amorphous silicon-hybride for laser release. There are several materials that may be used that are photo or thermal sensitive and the bonds can be broken using laser or ultra-violet (UV) mechanisms.

In illustrative embodiments, for glass handle wafers or panels, when utilizing laser release techniques with a UV laser, a carbon deposited release layer can be used for absorption of UV laser light and release between the glass handle wafer (panel) and an adhesive. Carbon or UV absorbing metal particles added to a polymer such as, for example, polyimide (PI) (e.g., PI adhesive) may be used for UV absorption and release between a glass wafer and an active wafer. Other options for laser wavelength and release with different mechanisms such as, for example, ablation of a release layer or shock wave release, are possible for organic or inorganic bonded samples. For a silicon handle wafer, when using laser release with an infra-red (IR) laser, a release layer including a thin metal with high IR laser absorption such as, for example, Al, Ti or alternate material along with adhesive material such as PI or epoxy material can be used. The laser can cause separation by ablation of the release layer for a polymer to silicon or silicon modified surface layer, or separation by ablation or shock wave release or alternate mechanism from a laser between a silicon handle wafer and a bonded wafer or component.

FIGS. 6A, 6B and 6C depict high-level cross-sectional views of the respective test substrates 219, 319 and 419 with different types of contacts bonded to the respective DUT substrates 229, 329 and 429. The bonding process includes cleaning substrate (e.g., wafer) surfaces and joining the test substrates 219, 319 and 429 to the DUT substrates 229, 329 and 429 including joining functional hardware of the test substrates 219, 319 and 419 to functional hardware of the DUT substrates 229, 329 and 429. The bonding process may use, for example, fluxless thermal compression bonding, fluxless reflow, laser bonding or an alternate bonding process. As can be seen in FIGS. 6A-6C, the bonding creates physical and electrical contact of the pins 212, pads 312 and alternative conductive contacts 412 to the conductive contacts 222, 322 and 422, respectively. In some cases, the intermediate layers 226, 326 and 426 are respectively disposed between and contact the pins 212, pads 312 and alternative conductive contacts 412 and the conductive contacts 222, 322 and 422.

Following bonding, a test of hardware is performed on devices of the DUT substrates 229, 329 and 429 through test probes contacting the conductive contacts 210, 310 and 410 to, for example, apply signals to the conductive contacts 210, 310 and 410 and/or measure signals at the conductive contacts 210, 310 and 410. As noted herein, the test probes can be available or customized test probes spaced apart from each other at the same pitch as the conductive contacts 210, 310 and 410. The test probes can be, for example, part of automated test equipment (ATE) that stores data for different types of diagnostics (e.g., known good, partial good, trending, artificial intelligence, etc.).

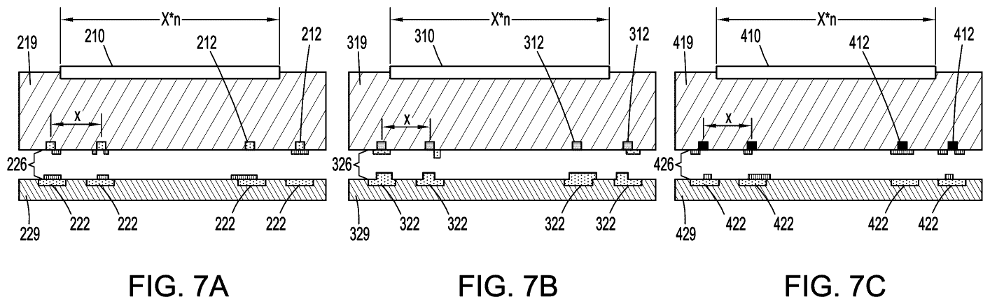

FIGS. 7A, 7B and 7C depict high-level cross-sectional views of the respective test substrates 219, 319 and 419 with different types of contacts following de-bonding from the respective DUT substrates 229, 329 and 429. Following completion of the testing, the respective test substrates 219, 319 and 419 are separated from the respective DUT substrates 229, 329 and 429. The separation is performed using, for example, dielectric or adhesive laser debonding utilizing a scanning laser, ultra-violet (UV) laser, infra-red (IR) laser or alternate electro-magnetic energy source. As can be seen in FIGS. 7A-7C, following de-bonding, portions of the intermediate layers 226, 326, 426 and/or other residual materials that may remain on the respective test substrates 219, 319 and 419 and/or on the respective DUT substrates 229, 329 and 429. For example, the de-bonding process may cause some damage to or loss of all or portions of the intermediate layers 226, 326, 426. Such damage or loss can be caused by, for example, shearing or pulling of the intermediate layers 226, 326, 426 occurring during de-bonding.

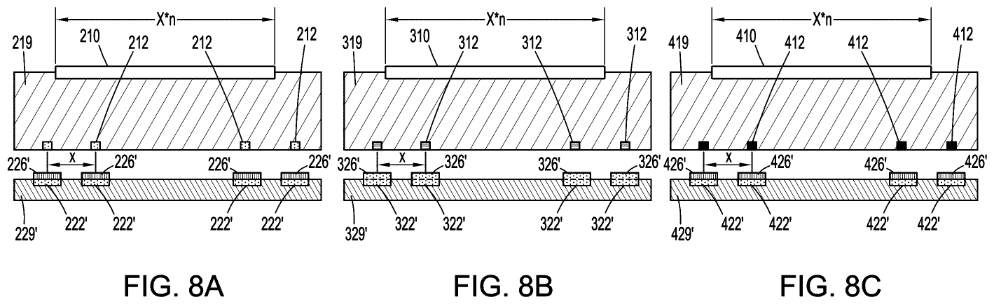

FIGS. 8A, 8B and 8C depict high-level cross-sectional views of the respective test substrates 219, 319 and 419 with different types of contacts following preparation for subsequent bonding to respective additional DUT substrates 229′, 329′ and 429′. In more detail, the respective test substrates 219, 319 and 419 are cleaned and re-processed to remove the portions of the intermediate layers 226, 326, 426 and/or other residual materials that may remain on the respective test substrates 219, 319 and 419. The functional hardware surfaces of the respective test substrates 219, 319 and 419 are cleaned and re-processed. The cleaning and re-processing prepares the respective test substrates 219, 319 and 419 to be re-used in connection with testing of devices on additional DUT substrates 229′, 329′ and 429′, which may be prepared in the same or a similar manner as the DUT substrates 229, 329 and 429 discussed in connection with FIGS. 5A-5C. Like the DUT substrates 229, 329 and 429, intermediate layers 226′, 326′ and 426′ are respectively deposited on the surfaces of conductive contacts 222′, 322′ and 422′ of the additional DUT substrates 229′, 329′ and 429′. The intermediate layers 226′, 326′ and 426′ may be the same as or similar to the intermediate layers 226, 326 and 426 and the conductive contacts 222′, 322′ and 422′ may be the same as or similar to the conductive contacts 222, 322 and 422. The cleaning and re-processing can include, for example, chemical processes, plasma processes, mechanical processes, chemical-mechanical processes (e.g., chemical mechanical planarization (CMP)), lithography, plating, or other process steps.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETS, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

As noted above, the embodiments provide techniques and structures for forming semiconductor testing structures. Advantageously, the illustrative embodiments permit testing of smaller (e.g., ultra-fine) pitch interconnects by adding a test layer to step-up pitch and dimensions of probe contact points to meet probe technology limits that are not in conformance with the smaller pitches and dimensions of device interconnects. As an additional advantage, the embodiments leave the device interconnects in a condition for proper operation after the test layer is removed. By including DFT circuits on a test substrate, the embodiments further enable the utilization of complex DFT circuits without burdening the designs of the DUTs with the extra circuitry. The probe contact points on the test layer can be uniform in pattern and utilized for many different products, which means that one standardized set of probes may be used for multiple products, thereby reducing cost (e.g., in some cases by millions of dollars).

In one embodiment, a semiconductor test structure includes a first surface including a plurality of first conductive contacts spaced apart from each other at a first pitch, and a second surface located opposite the first surface and including a plurality of second conductive contacts spaced apart from each other at a second pitch. The second pitch is less than the first pitch, and respective ones of the plurality of first conductive contacts are electrically connected to one or more respective ones of the plurality of second conductive contacts.

Respective ones of the plurality of first conductive contacts may be electrically connected to the one or more respective ones of the plurality of second conductive contacts via one or more circuits. The semiconductor test structure may further include a plurality of wires electrically connecting the respective ones of the plurality of first conductive contacts to the one or more respective ones of the plurality of second conductive contacts.

The respective ones of the plurality of second conductive contacts may be configured to electrically contact respective ones of a plurality of third contacts of a DUT. The second pitch may be the same as a pitch at which the respective ones of the plurality of third conductive contacts are spaced apart from each other. The first pitch may be the same as a pitch at which respective ones of a plurality of test probes are spaced apart from each other.

The plurality of first conductive contacts may include at least one of a plurality of conductive pads and a plurality of conductive bumps. The plurality of second conductive contacts may include at least one of a plurality of probe tips, a plurality of scrub tips, a plurality of pins, a plurality of vias, a plurality of pillars and a plurality of wires.

The semiconductor test structure may further include one or more circuits, wherein the one or more circuits include at least one of a PLL circuit, a microcontroller, a BIST engine and a sensor. The semiconductor test structure may further include an RDL, wherein the one or more circuits are wired to the RDL, and wherein the RDL is configured to distribute one or more signals applied to the one or more circuits to one or more interconnects of a DUT. The respective ones of the plurality of first conductive contacts may be electrically connected to the one or more respective ones of the plurality of second conductive contacts via the one or more circuits.

The semiconductor test structure may be configured to be bonded to and de-bonded from a DUT. The semiconductor test structure may be configured to be bonded to a silicon probe card.

In another embodiment, a semiconductor test structure includes a plurality of first conductive contacts disposed on a first side of the semiconductor test structure, wherein the plurality of first conductive contacts are spaced apart from each other at a first pitch, and a plurality of second conductive contacts spaced apart from each other at a second pitch and disposed on a second side of the semiconductor test structure. The second side is located opposite the first side, and the second pitch is less than the first pitch. Respective ones of the plurality of first conductive contacts are electrically connected to one or more respective ones of the plurality of second conductive contacts.

The respective ones of the plurality of first conductive contacts may be electrically connected to the one or more respective ones of the plurality of second conductive contacts via one or more circuits. The respective ones of the plurality of second conductive contacts may be configured to electrically contact respective ones of a plurality of third contacts of a device under test. The second pitch may be the same as a pitch at which the respective ones of the plurality of third conductive contacts are spaced apart from each other.

In another embodiment, a semiconductor test structure includes a first substrate bonded to a second substrate, a plurality of first conductive contacts disposed on a first side of the first substrate, wherein the plurality of first conductive contacts are spaced apart from each other at a first pitch, and a plurality of second conductive contacts spaced apart from each other at a second pitch and disposed on a second side of the first substrate. The second side is located opposite the first side, and the second pitch is less than the first pitch. Respective ones of the plurality of first conductive contacts are electrically connected to one or more respective ones of the plurality of second conductive contacts. The second substrate includes a plurality of third contacts of a device under test and the respective ones of the plurality of second conductive contacts electrically contact respective ones of the plurality of third contacts.

The respective ones of the plurality of third conductive contacts may be spaced apart from each other at the second pitch. The respective ones of the plurality of first conductive contacts may be electrically connected to the one or more respective ones of the plurality of second conductive contacts via one or more circuits.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as +5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor test structure comprising:
a first surface comprising a plurality of first conductive contacts spaced apart from each other at a first pitch; and
a second surface located opposite the first surface and comprising a plurality of second conductive contacts spaced apart from each other at a second pitch;
wherein the second pitch is less than the first pitch; and
wherein respective ones of the plurality of first conductive contacts are electrically connected to one or more respective ones of the plurality of second conductive contacts.

2. The semiconductor test structure of claim 1, wherein the respective ones of the plurality of first conductive contacts are electrically connected to the one or more respective ones of the plurality of second conductive contacts via one or more circuits.

3. The semiconductor test structure of claim 1, further comprising a plurality of wires electrically connecting the respective ones of the plurality of first conductive contacts to the one or more respective ones of the plurality of second conductive contacts.

4. The semiconductor test structure of claim 1, wherein the respective ones of the plurality of second conductive contacts are configured to electrically contact respective ones of a plurality of third conductive contacts of a device under test.

5. The semiconductor test structure of claim 4, wherein the second pitch is the same as a pitch at which the respective ones of the plurality of third conductive contacts are spaced apart from each other.

6. The semiconductor test structure of claim 1, wherein the plurality of first conductive contacts comprise at least one of a plurality of conductive pads and a plurality of conductive bumps.

7. The semiconductor test structure of claim 1, wherein the plurality of second conductive contacts comprise at least one of a plurality of probe tips, a plurality of scrub tips, a plurality of pins, a plurality of vias, a plurality of pillars and a plurality of wires.

8. The semiconductor test structure of claim 1, wherein the first pitch is the same as a pitch at which respective ones of a plurality of test probes are spaced apart from each other.

9. The semiconductor test structure of claim 1, further comprising one or more circuits, wherein the one or more circuits comprise at least one of a phase locked loop circuit, a microcontroller, a built-in self-test engine and a sensor.

10. The semiconductor test structure of claim 9, further comprising a redistribution layer, wherein the one or more circuits are wired to the redistribution layer, and wherein the redistribution layer is configured to distribute one or more signals applied to the one or more circuits to one or more interconnects of a device under test.

11. The semiconductor test structure of claim 9, wherein the respective ones of the plurality of first conductive contacts are electrically connected to the one or more respective ones of the plurality of second conductive contacts via the one or more circuits.

12. The semiconductor test structure of claim 1, wherein the semiconductor test structure is configured to be bonded to and de-bonded from a device under test.

13. The semiconductor test structure of claim 1, wherein the semiconductor test structure is configured to be bonded to a silicon probe card.

14. A semiconductor test structure comprising:
a plurality of first conductive contacts disposed on a first side of the semiconductor test structure, wherein the plurality of first conductive contacts are spaced apart from each other at a first pitch; and
a plurality of second conductive contacts spaced apart from each other at a second pitch and disposed on a second side of the semiconductor test structure;
wherein the second side is located opposite the first side;
wherein the second pitch is less than the first pitch; and
wherein respective ones of the plurality of first conductive contacts are electrically connected to one or more respective ones of the plurality of second conductive contacts.

15. The semiconductor test structure of claim 14, wherein the respective ones of the plurality of first conductive contacts are electrically connected to the one or more respective ones of the plurality of second conductive contacts via one or more circuits.

16. The semiconductor test structure of claim 14, wherein the respective ones of the plurality of second conductive contacts are configured to electrically contact respective ones of a plurality of third conductive contacts of a device under test.

17. The semiconductor test structure of claim 16, wherein the second pitch is the same as a pitch at which the respective ones of the plurality of third conductive contacts are spaced apart from each other.

18. A semiconductor test structure comprising:
a first substrate bonded to a second substrate;
a plurality of first conductive contacts disposed on a first side of the first substrate, wherein the plurality of first conductive contacts are spaced apart from each other at a first pitch; and
a plurality of second conductive contacts spaced apart from each other at a second pitch and disposed on a second side of the first substrate;
wherein the second side is located opposite the first side;
wherein the second pitch is less than the first pitch;
wherein respective ones of the plurality of first conductive contacts are electrically connected to one or more respective ones of the plurality of second conductive contacts; and
wherein the second substrate comprises a plurality of third conductive contacts of a device under test and the respective ones of the plurality of second conductive contacts electrically contact respective ones of the plurality of third conductive contacts.

19. The semiconductor test structure of claim 18, wherein the respective ones of the plurality of third conductive contacts are spaced apart from each other at the second pitch.

20. The semiconductor test structure of claim 18, wherein the respective ones of the plurality of first conductive contacts are electrically connected to the one or more respective ones of the plurality of second conductive contacts via one or more circuits.
